(19) United States
(12) Patent Application Publication
(10) Pub. No.: US 2007/0104304 A1
(43) Pub. Date: May 10, 2007

(54) SEMICONDUCTOR DEVICE

(75) Inventor: Morio TAKAHASHI, Saitama-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/556,412

(22) Filed: Nov. 3, 2006

(30) Foreign Application Priority Data
Nov. 4, 2005 (JP) 2005-320537

(51) Int. Cl. H03D 3/24

(52) U.S. Cl. 375/375

(57) ABSTRACT

A semiconductor device includes: a signal generating circuit which outputs a repetitive signal; an offset signal generating circuit which outputs an offset signal; a first comparator; and a second comparator. The first comparator compares the repetitive signal with a reference signal and outputs a first control signal during a period in which the repetitive signal is higher than the reference signal, The second comparator compares a level-shifted repetitive signal with the reference signal and outputs a second control signal during a period in which the level-shifted repetitive signal is higher than the reference signal. The level-shifted repetitive signal is obtained by shifting the level of the repetitive signal by the offset signal.

### CROSS-REFERENCE TO RELATED APPLICATION

This application is based upon and claims the benefit of priority from the prior Japanese Patent Application No.2005-320537, filed on Nov. 4, 2005; the entire contents of which are incorporated herein by reference

### BACKGROUND

One of the power supply circuits is a synchronous rectification DC-DC converter. In this converter, a highside and lowside transistor connected in series between the supply voltage and the reference voltage are alternately turned on and off, and the ON period of the transistors is varied in response to the change of the load and the input voltage. Thus the converter outputs DC voltage controlled by a PWM (Pulse Width Modulation) input signal.

At the timing for this on/off switching, if there is any period in which the upper transistor and the lower transistor are simultaneously turned on, a through current flows and as the result decreases the conversion efficiency Therefore, the timing for switching the upper transistor and the lower transistor is delayed to provide a period (dead time) in which they are simultaneously turned off.

Conventionally, a delay circuit with a CR time constant of a capacitor C and a resistor R is used to delay the timing for switching the upper transistor and the lower transistor. However, this method requires a time for charging/discharging the capacitor C, which presents a problem of disturbing for rapidly switching. Furthermore, inverters and buffers used in the delay circuit have varied thresholds, which present a problem of causing variation in dead time.

In this regard, a method is disclosed for delaying the timing for switching by comparing a triangular signal with two reference voltages having different levels (e.g., JP 3-155394A).

The circuit for driving the load disclosed in JP 3-155394A comprises a first differential amplifier and a second differential amplifier. The first differential amplifier compares a nearly triangular signal with a first bias voltage and outputs a prescribed signal for driving a output circuit during a period in which the level of the triangular signal is lower than the first bias voltage. The second differential amplifier compares the triangular signal with a second bias voltage having a higher level than the first bias voltage and outputs a prescribed signal for driving a output circuit during a period in which the level of the triangular signal is higher than the second bias voltage. Thus the circuit for driving the load drives loads connected in parallel between the supply voltage and the reference voltage.

However, the circuit for driving the load disclosed in JP 3-155394A obtains the first and second bias voltage by dividing the supply voltage using a resistor. Hence there is a problem of varied dead time due to the variation of the first and second bias voltage in response to the change of supply voltage.

Furthermore, there is no disclosure as to driving an output circuit having a first and second transistor connected in series between the supply voltage and the reference voltage.

### SUMMARY

According to an aspect of the invention, there is provided a semiconductor device Including: a signal generating circuit which outputs a repetitive signal; an offset signal generating circuit which outputs an offset signal; a first comparator which compares the repetitive signal with a reference signal and outputs a first control signal during a period in which the repetitive signal is higher than the reference signal; and a second comparator which compares a level-shifted repetitive signal with the reference signal and outputs a second control signal during a period in which the level-shifted repetitive signal is higher than the reference signal, the level-shifted repetitive signal being obtained by shifting the level of the repetitive signal by the offset signal.

According to the other aspect of the invention, there is provided a semiconductor device including: a signal generating circuit which outputs a repetitive signal; an offset signal generating circuit which outputs an offset signal; a first comparator which compares the repetitive signal with a reference signal and outputs a first control signal during a period in which the repetitive signal is higher than the reference signal; and a second comparator which compares a level-shifted reference signal with the repetitive signal and outputs a second control signal during a period in which the repetitive signal is higher than the level-shifted reference signal, the level-shifted reference signal being obtained by shifting the level of the reference signal by the offset signal.

### BRIEF DESCRIPTION OF THE DRAWINGS

FIG. 1 is a circuit diagram showing the configuration of a semiconductor device according to a first embodiment;

FIG. 2 is a circuit diagram showing a signal generating circuit according to the first embodiment;

FIG. 3 is a timing chart showing the operation of the semiconductor device circuit according to the first embodiment;

FIG. 4 shows the semiconductor device according to the first embodiment;

FIG. 5 is a circuit diagram showing the configuration of a semiconductor device according to a second embodiment;

FIG. 6 is a timing chart showing the operation of the semiconductor device according to the second embodiment;

FIG. 7 is a circuit diagram showing the relevant part of a semiconductor device according to a third embodiment;

FIG. 8 is a circuit diagram showing the variable constant current source according to the third embodiment;

FIG. 9 is a timing chart showing the operation of the semiconductor device according to the third embodiment;

FIG. 10 is a circuit diagram showing the relevant part of a semiconductor device according to a fourth embodiment;

FIG. 11 is a circuit diagram showing the variable constant current source according to the fourth embodiment;

FIG. 12 is a timing chart showing the operation of the semiconductor device according to the fourth embodiment;

FIG. 13 shows a semiconductor device according to another embodiment; and

FIG. 14 is a circuit diagram showing the configuration of a semiconductor device according to another embodiment.

### DETAILED DESCRIPTION

Embodiments of the invention will now be described with reference to the drawings, In the drawings, some of components equivalent to each other are labeled with common reference numerals, and their detailed explanations may be omitted.

First Embodiment

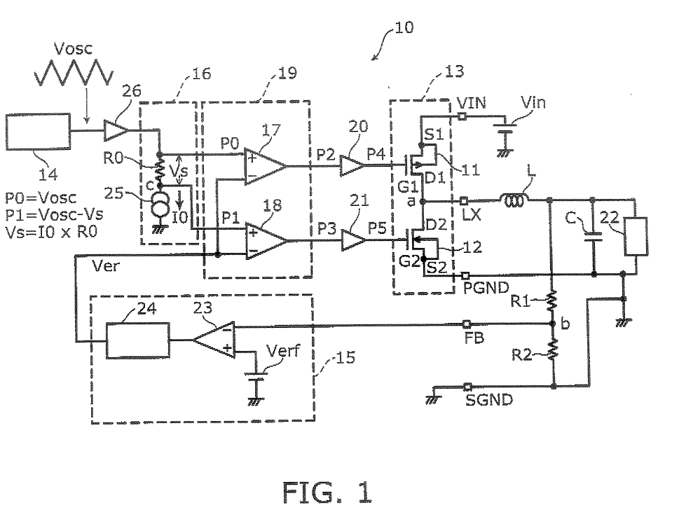

A semiconductor device according to a first embodiment is described with reference to FIGS. 1-3. As shown in FIG. 1, the semiconductor device 10 according to this embodiment comprises an output circuit 13 having a first transistor 11 and a second transistor 12 connected in series between an input power supply Vin and a reference voltage PGND, a signal generating circuit 14 which outputs a prescribed repetitive signal Vosc, a reference signal generating circuit 15 which outputs a prescribed reference signal Ver, an offset signal generating circuit 16 which outputs a prescribed offset signal Vs, and a control circuit 19 having a first and second comparator 17, 18 which compares the repetitive signal Vosc with the reference signal Ver and outputs a control signal for driving the output circuit 13 in response to the comparison result.

In the output circuit 13, the first transistor 11 is illustratively a p-type field effect transistor with an insulated gate (hereinafter referred to as p-MOS transistor), and the second transistor 12 is illustratively an n-type field effect transistor with an insulated gate (hereinafter referred to as n-MOS transistor), connected to each other in the so-called totem pole configuration.

The source S1 of the first transistor 11 is connected to an input power supply terminal Vin. The drain D1 of the first transistor 11 is connected to the drain D2 of the second transistor 12. The connection node (a) with the drain D1 of the first transistor 11 and the drain D2 of the second transistor 12 is connected to an output terminal LX. The source S2 of the second transistor 12 is connected to the reference source terminal PGND, The gates G1, G2 of the first and second transistor 11, 12 are connected to the output terminals of the first and second comparator 17, 18 of the control circuit 19 via buffers 20, 21, respectively,

A rectification circuit made of an inductor L and a capacitor C for rectifying the PWM-controlled output signal of the output circuit 13 is connected to the output terminal LX. For example, for a voltage variation of 3 to 5 V of the input power supply Vin, a rectified output voltage Vout of about 1.2 to 3.3 V is applied to a load 22.

A series circuit of resistors R1, R2 is connected in parallel to the load 22. The connection node (b) with the resistors R1, R2 is connected to a feedback terminal FB. The output voltage Vout of the semiconductor device 10 is voltage divided by the resistors R1, R2 and inputted to the reference signal generating circuit 15 via the feedback terminal FB.

The reference signal generating circuit 15 serves to detect the amount of deviation of the output voltage Vout from a prescribed value and as the result to conduct a feedback control so that the output voltage Vout is matched to the prescribed value. The reference signal generating circuit 15 includes an operational amplifier 23 with a noninverted input terminal connected to a reference power supply Vref and a inverted input terminal connected to the feedback terminal FB, The reference signal generating circuit 15 outputs a reference signal Ver used for the feedback control so that the voltage of the reference power supply Vref and the voltage divided by the resistors R1, R2 are matched.

A phase compensation circuit 24 connected to the output terminal of the operational amplifier 23 includes, for example, a CR advanced phase circuit made of a resistor and a capacitor, and serves to prevent the abnormal oscillation of the semiconductor device 10,

The offset signal generating circuit 16 has a series circuit of a constant current source 25 and a resistor R0. One end of the resistor R0 is connected to the signal generating circuit 14 via a buffer 26, and one end of the constant current source 25 is grounded. An offset voltage is given by Vs=I0×R0, where I0 denotes the current of the constant current source 25.

The first comparator 17 has a noninverted input terminal connected to the signal generating circuit 14 via a buffer 26 and a inverted input terminal connected to the reference signal generating circuit 15

The second comparator 18 has a positive input terminal connected to the connection node (c) with the resistor R0 and the constant current source 25 and a inverted input terminal connected to the reference signal generating circuit 15.

Thus a signal P0 equal to the repetitive signal Vosc is inputted to the noninverted input terminal of the first comparator 17. A signal P1=Vosc−Vs, which is obtained by subtracting the offset signal Vs from the repetitive signal Vosc, is inputted to the noninverted input terminal of the second comparator 18.

The first comparator 17 compares the repetitive signal Vosc with the reference signal Ver and outputs a first control signal P2 which turns off the first transistor 11 during a period in which the repetitive signal Vosc is higher than the reference signal Ver. The second comparator 18 compares the repetitive signal Vosc−Vs with the reference signal Ver and as the result outputs a second control signal P3 which turns on the second transistor 12 during a period in which the repetitive signal Vosc−Vs is higher than the reference signal Ver,

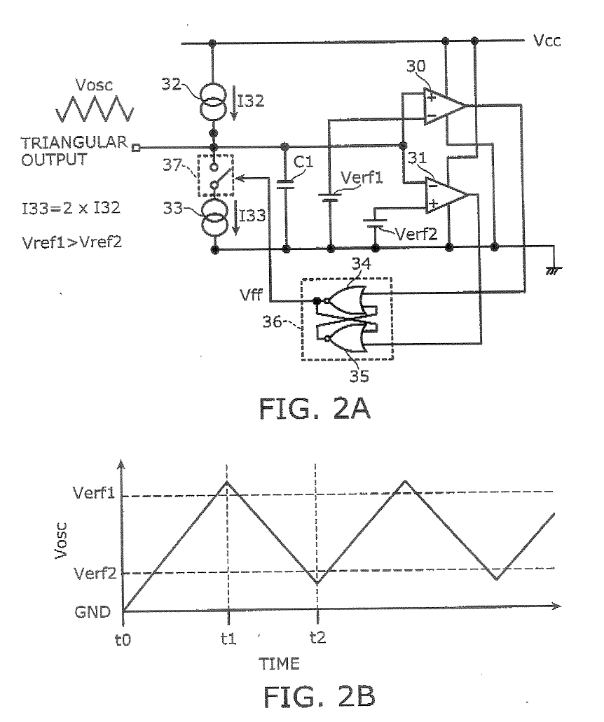

As shown in FIG. 2A, the signal generating circuit 14 comprises comparators 30, 31, constant current sources 32, 33, a flip-flop 36 with NOR circuits 34, 35, reference power supplies Vref1, Vref2, a capacitor C1, and a switch 37,

The current I33 of the constant current source 33 is set to double the current I32 of the constant current source 32. The voltage of the reference power supply Vref1 is set larger than the voltage of the reference power supply Vref2. The switch 37 is configured to be turned off when the output Vff of the flip-flop 36 is L.

First, when the power supply Vcc is applied at time t0, the output of the comparator 30 becomes L, the output of the comparator 31 becomes H, the output Vff of the flip-flop 36 becomes L, and the switch 37 is turned off.

Next, to charge the capacitor C1 by the constant current source 32 starts. The voltage of the capacitor C1 rises from 0 V according to Vosc=I32×t/C1, where t is the time and C1 is the capacitance of the capacitor C1.

When the repetitive signal Vosc exceeds Vref2, the output of the comparator 31 is inverted to L. However, because the output Vff of the flip-flop 36 retains L, the switch 37 maintains the OFF state, and charging of the capacitor C1 is continued.

When the repetitive signal Vosc reaches Vref1, the output of the comparator 30 is inverted to H, the output Vff of the flip-flop 36 is inverted to H, and the switch 37 is turned on. With regard to the amount of the current, the difference between the current I33 and the current I32 equals the current I32. When the capacitor C1 begins to discharge, the voltage of the capacitor C1 falls according to Vosc=−I32×t/C1.

The repetitive signal Vosc immediately becomes lower than Vref1, and the output of the comparator 30 becomes L. However, because the output Vff of the flip-flop 36 retains H, the switch 37 maintains the ON state, and discharging of the capacitor C1 is continued, This switching point is referred to as time t1.

When the repetitive signal Vosc reaches Vref2 and the output of the comparator 31 is inverted to H, the output Vff of the flip-flop 36 becomes L, and the switch 37 is turned off. Thus the capacitor C1 begins to be charged again. This switching point is referred to as time t2.

As shown in FIG. 2B, the operation described above is repeated, and a triangular repetitive signal Vosc is outputted The repetition cycle T is expressed as T=2×(t2−t1).

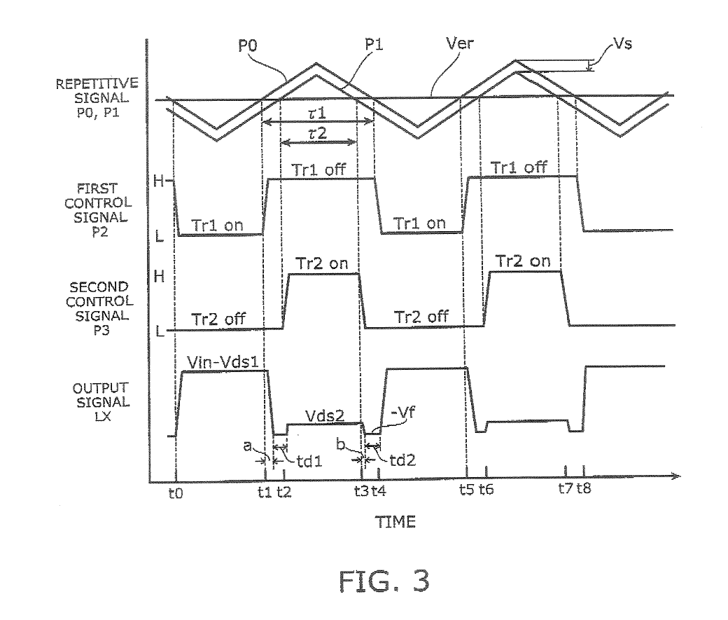

As shown in FIG. 3, when the triangular repetitive signal P0 becomes higher than the reference signal Ver at time t1, the first control signal P2 is turned from L to H, and the first transistor 11 is turned off. When the repetitive signal P0 becomes lower than the reference signal Ver at time t4, the first transistor 11 is turned on. The period in which the repetitive signal P0 is higher than the reference signal Ver is τ1=t4−t1.

Likewise, when the repetitive signal P1 becomes higher than the reference signal Ver at time t2, the second control signal P3 is turned from L to H, and the second transistor 12 is turned on. When the repetitive signal P1 becomes lower than the reference signal Ver at time t3, the second transistor 12 is turned off. The period in which the repetitive signal P1 is higher than the reference signal Ver is τ2=t3−t2.

The turn-on timing t2 of the second transistor 12 has a phase delay relative to the turn-off timing t1 of the first transistor 11. Therefore, between the times t1 and t2, except the fall time (a) of the first transistor 11, a dead time td1 is obtained in which the first and second transistor are both turned off.

Likewise, the turn-off timing t3 of the second transistor 12 has a advanced phase relative to the turn-on timing t1 of the first transistor 11. Therefore, between the times t3 and t4, except the fall time (b) of the second transistor 12, a dead time td2 is obtained in which the first and second transistor are both turned off.

The output signal LX exhibits a voltage (Vin−Vds1) obtained by subtracting the turn-on voltage of the first transistor 11 from the voltage of the input power supply Vin during a period in which the first transistor 11 is turned on and the second transistor 12 is turned off. The output signal LX exhibits the turn-on voltage (Vds2) of the second transistor 12 during a period in which the first transistor 11 is turned off and the second transistor 12 is turned on.

During the dead time in which the first and second transistor 11, 12 are both turned off, energy stored in the inductor L flows through the parasite diode of the second transistor 12 as a regenerative current. Thus the output signal LX exhibits a forward voltage (−Vf) of the parasitic diode.

Thus the delay time of the output signal LX of the output circuit 13 is determined by the gate delay time of the control circuit 19 and the delay time of the first and second transistor 11, 12. Hence the response time of the output signal LX can be reduced relative to the case of delaying the turn-on timing of the first and second transistor 11, 12 using a CR time constant circuit. Therefore the variation of the dead times td1, td2 can be prevented, and dead times td1, td2 with an equal value can be obtained because a symmetric triangular wave is used as a repetitive signal Vosc.

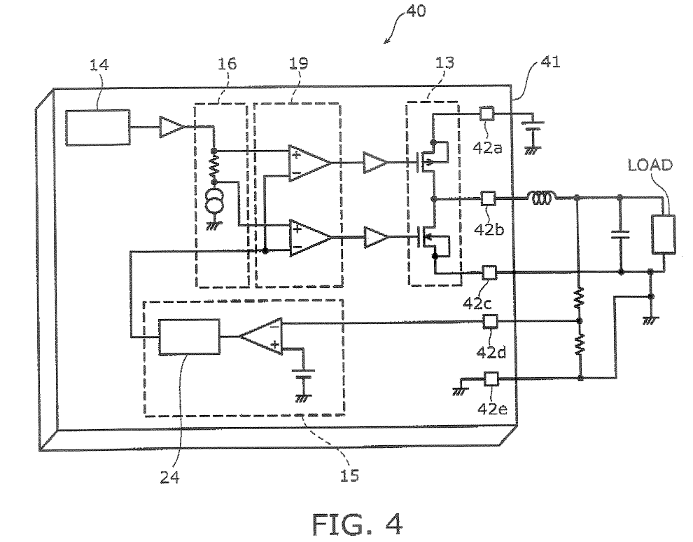

A semiconductor device on a single chips according to this embodiment is described with reference to FIG. 4.

As shown in FIG. 4, the semiconductor device 40 of this embodiment comprises an output circuit 13 having a first transistor 11 and a second transistor 12 connected in series, a signal generating circuit 14 which outputs a prescribed repetitive signal Vosc, a reference signal generating circuit 15 which outputs a prescribed reference signal Ver, an offset signal generating circuit 16 which outputs a prescribed offset signal Vs, and a control circuit 19 with a first and second comparator 17, 18 which compares the repetitive signal Vosc with the reference signal Ver and outputs a control signal for driving the output circuit 13 in response to the comparison result. These circuits are monolithically integrated on the same chip 41.

The first transistor 11 and the second transistor 12 of the output circuit 13 are configured as a CMOS circuit of a p-MOS transistor and an n-MOS transistor, for example, and preferably formed in a region shielded by a guard ring to avoid the switching noise on the surrounding circuits.

Furthermore, bonding pads 41a to 42e are formed on the semiconductor chip 41, which are required for externally outputting the PWM-controlled output voltage of the output circuit 13.

As described above, in this embodiment, the constant current source 25 and the resistor R0 are used to generate a stable offset voltage Vs, and the repetitive signal Vosc is level shifted by the offset signal Vs. Also, because the first and second comparator 17, 18 are integrated monolithically on a single chip 41, electrical characteristic can be easily equaled. Thus stable dead times td1, td2 are obtained. Furthermore, because equal dead times td1, td2 are obtained, the dead times can be reduced to improve the conversion efficiency. As a result, a semiconductor device capable of fast operation is obtained.

While the offset signal generating circuit 16 described herein has a series circuit of a constant current source 25 and a resistor R0, it can be configured as a circuit based on a constant voltage diode.

Furthermore, while the repetitive signal Vosc is described herein as a triangular wave, other repetitive signals such as a trapezoidal wave may be used.

Moreover, the first and second transistor 11, 12 of the output circuit 13 are described herein as MOS transistors, they can be configured as bipolar transistors or insulated gate bipolar transistors (IGBTs). When a bipolar transistor or IGBT is used, because it has no parasitic diode as opposed to the MOS transistor, a diode needs to be externally attached for allowing the regenerative current to escape

With regard to the semiconductor device 40, while the first and second transistor 11, 12 of the output circuit 13 are described herein as being monolithically integrated on the same chip 41, the output circuit 13 may be an external, discrete MOS transistor.

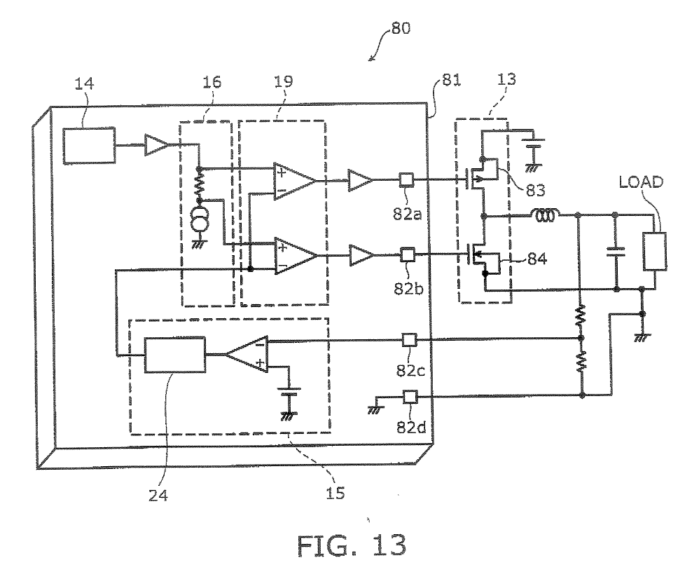

As shown in FIG. 13, a semiconductor device 80 comprises a signal generating circuit 14 which outputs a prescribed repetitive signal Vosc, a reference signal generating circuit 15 which outputs a prescribed reference signal Ver, an offset signal generating circuit 16 which outputs a prescribed offset signal Vs, and a control circuit 19 with a first and second comparator 17, 18 which compares the repetitive signal Vosc with the reference signal Ver and outputs a control signal for driving the output circuit 13 in response to the comparison result. These circuits are monolithically integrated on the same chip 81. An output circuit 13 having a discrete, first and second transistor 83, 84 is externally attached via bonding pads 82a to 82d formed on the semiconductor chip 81.

Because the output circuit 13 is externally attached, the semiconductor device 80 is not affected by heat generation and switching noise from the output circuit 13, and suited to a DC-DC converter with larger power consumption.

Second Embodiment

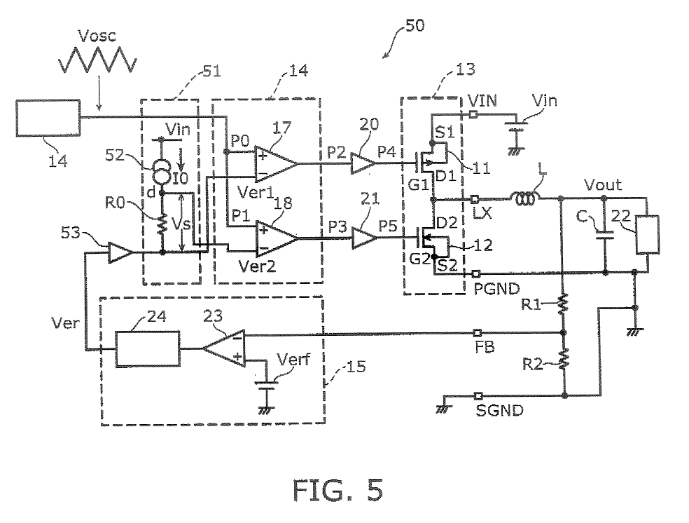

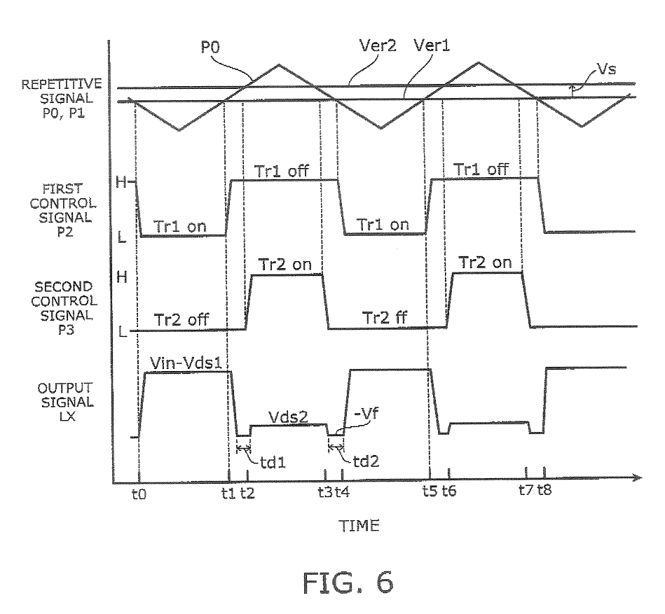

A semiconductor device circuit according to a second embodiment is described with reference to FIGS. 5 and 6. This embodiment is different from the first embodiment In that the reference signal Ver is level shifted by the offset signal Vs.

As shown in FIG. 5, the offset signal generating circuit 51 of the power supply circuit 50 has a series circuit of a constant current source 52 and a resistor R0. One end of the constant current source 52 is connected to the input power supply Vin, and one end of the resistor R0 is connected to the reference signal generating circuit 15 via a buffer 53. An offset voltage is given by Vs=I0×R0, where I0 denotes the current of the constant current source 52.

The first comparator 17 has a noninverted input terminal connected to the signal generating circuit 14 and a inverted input terminal connected to the output terminal of the buffer 53. The second comparator 18 has a noninverted input terminal connected to the signal generating circuit 14 and a inverted input terminal connected to the connection node (d) with the constant current source 52 and the resistor R0.

Thus a reference signal Ver1 equal to the reference signal Ver is applied to the inverted input terminal of the first comparator 17, A reference signal Ver2, which is obtained by adding the offset signal to the reference signal Ver and thereby larger than the reference signal Ver1, is applied to the inverted input terminal of the second comparator 18.

As shown in FIG. 6, because the reference signal Ver2 is level shifted by adding the offset signal Vs to the reference signal Ver1, the second control signal P3 becomes H at time t2 when the repetitive signal P0 becomes higher than the reference signal Ver2, and the second control signal P3 becomes L at time t3 when the repetitive signal P0 becomes lower than the reference signal Ver2. Thus the dead times td1, td2 in which the first and second transistor 11, 12 are both turned off can be stably obtained.

In the semiconductor device 50 of this embodiment, because the reference signal Ver, which is a DC signal, is level shifted by the offset signal Vs, the bandwidth of the repetitive signal Vosc is not limited by the resistor R0 of the offset signal generating circuit 51. Therefore the semiconductor device 50 is suited to faster operation, for example, to the operation at a switching frequency of several MHz.

Third Embodiment

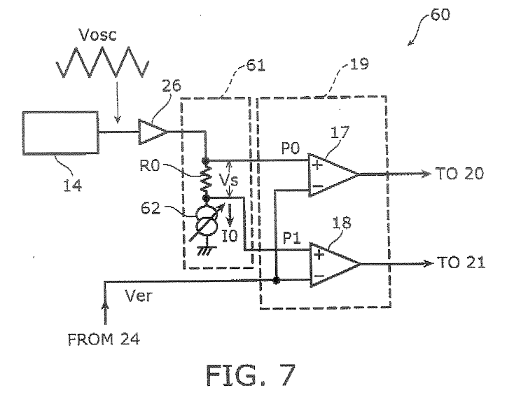

A semiconductor device according to a third embodiment of the invention is described with reference to FIGS. 7-9. This embodiment is different from the first embodiment in that the offset signal Vs is varied to allow the amount of level shift of the repetitive signal to be varied.

As shown in FIG. 7, the offset signal generating circuit 61 of the semiconductor device 60 has a series circuit of a resistor R0 and a variable constant current source 62. The variable constant current source 62 allows the current I0 to be varied, and thus the offset signal Vs can be varied.

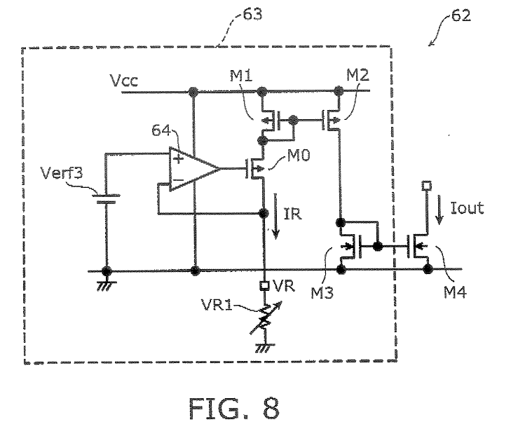

As shown in FIG. 8, the variable constant current source 62 has a current control circuit 63, which comprises an operational amplifier 64, a reference power supply Vref3 connected to the noninverted input terminal of the operational amplifier 64, a p-MOS transistor M0 having a gate connected to the output terminal of the operational amplifier 64, and current mirror circuits composed of p-MOS transistors M1, M2 and n-MOS transistors M3, M4.

In the constant voltage source of the feedback type composed of the reference power supply Vref3, the operational amplifier 64, and the MOS transistor M0, the operational amplifier 64 operates so that the reference power supply Vref3 equals the terminal voltage VR of the variable resistor VR1. Therefore the current can be controlled by the variable resistor VR1 connected between this terminal and the ground.

That is, because the current IR flowing through the variable resistor VR1 is given by IR=VR/VR1, the current IR is varied by varying the variable resistor VR1,

The current IR is outputted as a variable constant current Iout by the current mirror circuit composed of the p-MOS transistors M1, M2 and the current mirror circuit composed of the n-MOS transistors M3, M4.

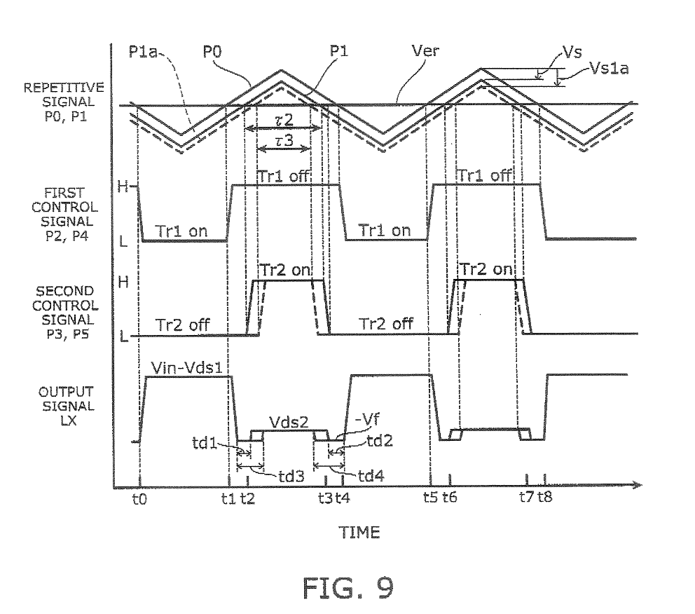

As shown in FIG. 9, the repetitive signal P1 is level shifted to P1a by varying the offset signal Vs from Vs1 to Vs1a. As a result, the time period in which the second transistor 12 is turned on is decreased from τ2 to τ3, and thus the dead times are increased from td1 td2 to td3, td4, respectively. Therefore, by varying the level of the offset signal Vs, the amount of level shift of the repetitive signal is varied, and thus the dead times can be varied.

The semiconductor device 60 of this embodiment allows the level of the offset signal Vs to be varied. Therefore, the dead times can be freely selected to meet user's requirements

Fourth Embodiment

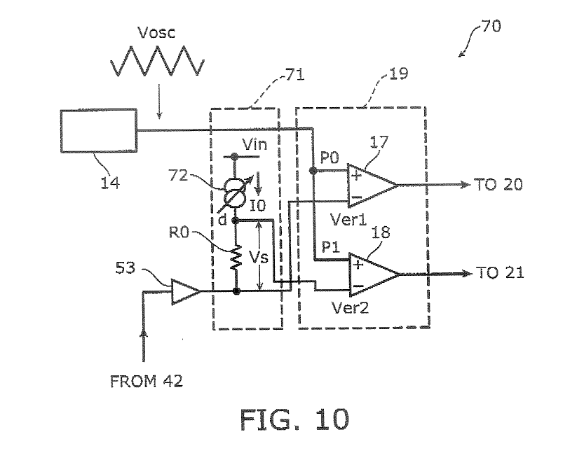

A semiconductor device according to a fourth embodiment is described with reference to FIGS. 10-12 This embodiment is different from the second embodiment in that the offset signal Vs is externally varied to allow the amount of level shift of the reference signal Ver to be varied.

As shown in FIG. 10, the offset signal generating circuit 71 of the semiconductor device 70 has a series circuit of a resistor R0 and a variable constant current source 72. The variable constant current source 72 allows the current I0 to be varied, and thus the offset signal Vs can be varied.

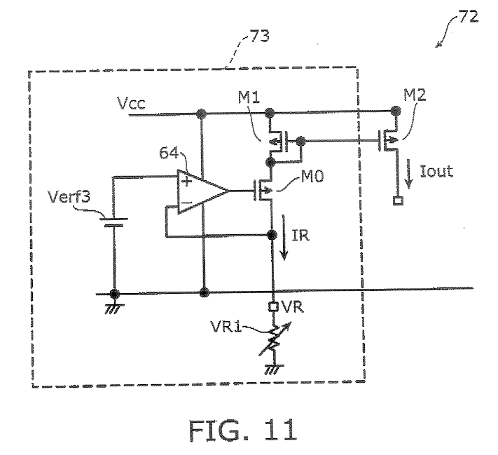

As shown in FIG. 11, the variable constant current source 72, which has a current control circuit 73, is connected to the power supply Vcc side, A current IR is outputted as a variable constant current Iout by a current mirror composed of p-MOS transistors M1, M2.

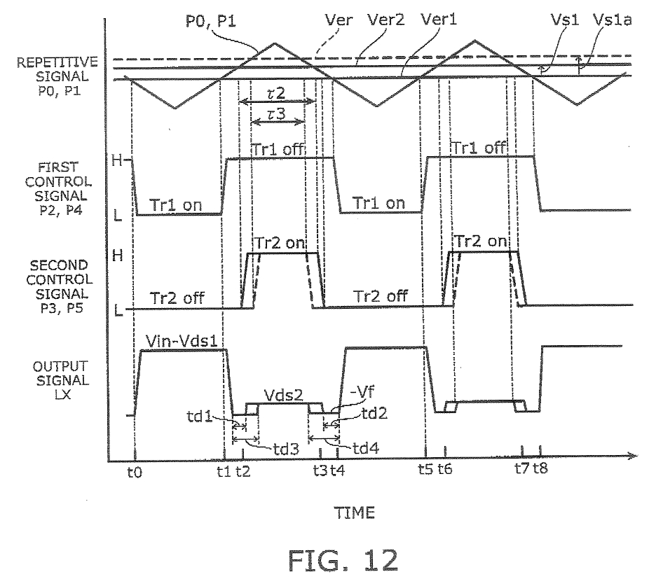

As shown in FIG. 12, the reference signal Ver is level shifted from Ver1 to Ver2 by varying the offset signal Vs from Vs1 to Vs1a. As a result, the time period in which the second transistor 12 is turned on is decreased from τ2 to τ3, and thus the dead times are increased from td1, td2 to td3, td4, respectively Therefore, by varying the level of the offset signal Vs, the amount of level shift of the reference signal Ver is varied, and thus the dead times can be varied.

As described above, the semiconductor device 70 of this embodiment allows the signal level of the reference signal Ver to be varied. Therefore, advantageously, the dead times can be freely selected to meet user's requirements, and the semiconductor device 70 is suited to faster operation.

Even without the reference signal generating circuit 15, the embodiments described above can also be operated as a semiconductor device by using an external reference signal.

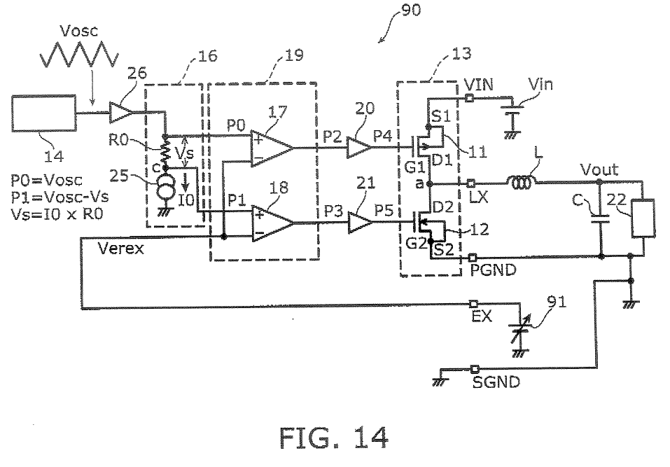

As shown in FIG. 14, an external reference signal generating circuit 91 is connected to the inverted input terminal of the comparators 17, 18 of the semiconductor device 90 via an external input terminal EX.

The output voltage Vout can be freely selected by varying the external reference signal Verex of the external reference signal generating circuit 91. For example, when the external reference signal Verex is increased, the period τ2 in which the first transistor 11 is turned off becomes shorter, and thus the output voltage Vout becomes higher. When the external reference signal Verex is decreased, the period τ2 in which the first transistor 11 is turned off becomes longer, and thus the output voltage Vout becomes lower. Furthermore, bipolar transistors or IGBTs can also be used as the first and second transistor.

1. A semiconductor device comprising:
a signal generating circuit which outputs a repetitive signal;
an offset signal generating circuit which outputs an offset signal;
a first comparator which compares the repetitive signal with a reference signal and outputs a first control signal during a period in which the repetitive signal is higher than the reference signal; and
a second comparator which compares a level-shifted repetitive signal with the reference signal and outputs a second control signal during a period in which the level-shifted repetitive signal is higher than the reference signal, the level-shifted repetitive signal being obtained by shifting the level of the repetitive signal by the offset signal.

2. The semiconductor device of claim 1, wherein the offset signal generating circuit varies the amount of level shift of the offset signal.

3. The semiconductor device of claim 2, wherein the offset signal generating circuit has a series circuit of a resistor and a variable constant current source.

4. The semiconductor device of claim 1, wherein the signal generating circuit, the offset signal generating circuits the first comparator and the second comparator are integrated on a single chip.

5. The semiconductor device of claim 1, wherein the repetitive signal is one of symmetric triangular wave and symmetric trapezoidal wave.

6. The semiconductor device of claim 1, further comprising a first and second transistor connected between a power supply voltage and a reference source, the first transistor being turned off by the first control signal, and the second transistor being turned on by the second control signal.

7. The semiconductor device of claim 6, wherein a period in which the first and second transistor are simultaneously turned off after the first control signal is outputted is equal to a period in which the first and second transistor are simultaneously turned off after the second control signal is outputted.

8. The semiconductor device of claim 6, further comprising: a smoothing circuit having an inductor of which one terminal is connected to a connection node with the first and second transistor, and capacitor which is connected between the other terminal of the inductor and a ground, a connection node with the capacitor and the inductor being an output terminal.

9. The semiconductor device of claim 8, further comprising a reference signal generating circuit which includes an operational amplifier, a reference power supply and a phase compensation circuit,
a inverted input terminal of the operational amplifier being connected to a connection node of a series circuit with two resistors connected between the output terminal and the ground,
a noninverted input terminal of the operational amplifier being connected to the reference power supply,
the operational amplifier output being inputted to the phase compensation circuit, and
the phase compensation circuit outputting the reference signal.

10. The semiconductor device of claim 1, wherein the reference signal is supplied from outside of the semiconductor device.

11. A semiconductor device comprising:
a signal generating circuit which outputs a repetitive signal;
an offset signal generating circuit Which outputs an offset signal;
a first comparator which compares the repetitive signal with a reference signal and outputs a first control signal during a period in which the repetitive signal is higher than the reference signal; and
a second comparator which compares a level-shifted reference signal with the repetitive signal and outputs a second control signal during a period in which the repetitive signal is higher than the level-shifted reference signal, the level-shifted reference signal being obtained by shifting the level of the reference signal by the offset signal.

12. The semiconductor device of claim 11, wherein the offset signal generating circuit varies the amount of level-shift of the offset signal.

13. The semiconductor device of claim 12, wherein the offset signal generating circuit has a series circuit of a resistor and a variable constant current source.

14. The semiconductor device of claim 11, wherein the signal generating circuit, the offset signal generating circuit, the first comparator and the second comparator are integrated on a single chip.

15. The semiconductor device of claim 11, wherein the repetitive signal is a symmetric triangular or trapezoidal wave.

16. The semiconductor device of claim 11, further comprising a first and second transistor connected between a power supply voltage and a reference source, the first transistor being turned off by the first control signal, and the second transistor being turned on by the second control signal.

17. The semiconductor device of claim 16, wherein a period in which the first and second transistor are simultaneously turned off after the first control signal is outputted is equal to a period in which the first and second transistor are simultaneously turned off after the second control signal is outputted.

18. The semiconductor device of claim 16, further comprising; a smoothing circuit having an inductor of which one terminal is connected to a connection node with the first and second transistor, and a capacitor which is connected between the other terminal of the inductor and a ground, a connection node with the capacitor and the inductor being an output terminal.

19. The semiconductor device of claim 18, further comprising a reference signal generating circuit which includes an operational amplifier, a reference power supply and a phase compensation circuit,
a inverted input terminal of the operational amplifier being connected to a connection node of a series circuit with two resistors connected between the output terminal and the ground,
a noninverted input terminal of the operational amplifier being connected to the reference power supply,
the operational amplifier output being inputted to the phase compensation circuit, and
the phase compensation circuit outputting the reference signal.

20. The semiconductor device of claim 11, wherein the reference signal is supplied from outside of the semiconductor device.
